(19) United States
(12) Patent Application Publication
(10) Pub. No.: US 2022/0308376 A1
(43) Pub. Date: Sep. 29, 2022

(54) ARRAY SUBSTRATE, MANUFACTURING METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Junling Liu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/056,616

(22) PCT Filed: Oct. 20, 2020
(86) PCT No.: PCT/CN2020/122191

§ 371 Date: Nov. 18, 2020

(30) Foreign Application Priority Data
Sep. 8, 2020 (CN) 202010932535.8

(51) Int. Cl. G02F 1/1368; G02F 1/1362; H01L 51/56; H01L 51/00; H01L 27/32

(52) U.S. Cl. CPC G02F 1/1368; G02F 1/136286; H01L 51/56; H01L 51/0097; H01L 27/3276; H01L 27/3248; H01L 2227/323; H01L 2251/306; H01L 2251/308

(57) ABSTRACT

An array substrate, a manufacturing method thereof, and a display panel are provided. The array substrate is divided into a display area and a bending area and includes a glass substrate and a flexible substrate. Wherein, the glass substrate is disposed corresponding to the display area, and the flexible substrate is disposed corresponding to the bending area. A plurality of bonding wirings in the bending area are respectively connected to a plurality of signal lines in the display area. The flexible substrate is bent to a back surface of the array substrate to perform chip on film (COF) bonding, thereby preventing a lower yield problem caused by using nano silver glues.

### FIELD OF INVENTION

The present disclosure relates to the field of display technologies, and more particularly, to an array substrate, a manufacturing method thereof, and a display panel.

### BACKGROUND OF INVENTION

With development of display technologies, bezel-free displays have become a mainstream of high-end products in current display market. The bezel-free displays have two advantages: first, they have beautiful appearances and are more fashionable, and second, displays using bezel-free techniques can better realize display splicing, such as a dual screen, a triple screen, or even a multiple screen. In addition, the bezel-free displays can bring a broader visual experience for users and eliminate restraints of original thick bezel displays.

At present, there are two methods to realize bezel-free or narrow bezels. One is a side surface bonding method, that is, shortening original peripheral bonding wirings or even shortening the original peripheral bonding wirings into a surface, printing a nano silver (Ag) glue on a side surface of an array substrate to connect the wirings, and then bonding a chip on film (COF) to the side surface of the array substrate, thereby realizing narrow bezels or bezel-free effect. Another one is a back surface bonding method, which is shortening original peripheral bonding wirings or even shortening the original peripheral bonding wirings into a surface, and using a back surface processing technique to perform a corresponding peripheral wiring design on a back surface. Then, similarly, a nano silver glue is printed on a side surface to be correspondingly connected to the wirings, correspondingly connecting the bonding wirings in a front surface to the peripheral wirings on the back surface, and at last, COF bonding is performed on the back surface, thereby realizing narrow bezels or bezel-free effect. However, both the above two bonding methods need to print the nano silver glue on the side surface of the array substrate, and limited by printing accuracy, in manufacturing processes, wirings inside the substrate often have short circuits caused by diffusion and penetration of silver ions or abnormal alignment of the nano silver glue, thereby causing a lower product yield and high cost. Therefore, bezel-free technique cannot be widely adopted and popularized.

Therefore, it is necessary to solve a lower yield problem caused by using the nano silver glue in current array substrate bonding process.

### SUMMARY OF INVENTION

The present disclosure provides an array substrate, a manufacturing method thereof, and a display panel to solve technical problems of a lower yield caused by using a nano silver glue in current array substrate bonding process.

To solve the above problems, an embodiment of the present disclosure provides technical solutions as follows.

An embodiment of the present disclosure provides an array substrate. The array substrate is divided into a display area and a bending area positioned on one side of the display area and includes a glass substrate and a flexible substrate. Wherein, the glass substrate corresponds to the display area, and the flexible substrate corresponds to the bending area and extends from the bending area to cover an upper surface of one side of the glass substrate in the display area. Wherein, the display area further includes a buffer layer, a thin film transistor, a plurality of signal lines, and a pixel electrode. The buffer layer is disposed on the glass substrate and is in contact with the flexible substrate. The thin film transistor is disposed on the buffer layer and the flexible substrate. The plurality of signal lines are disposed on a same layer as a gate electrode of the thin film transistor. The pixel electrode is disposed on the thin film transistor and is connected to the thin film transistor. The bending area further includes a plurality of bonding wirings disposed on the flexible substrate and respectively connected to the signal lines in the display area. Wherein, the flexible substrate in the bending area is bent along the one side of the glass substrate to one surface of the glass substrate away from the thin film transistor.

In the array substrate provided by the embodiment of the present disclosure, a material of the flexible substrate includes polyimide.

In the array substrate provided by the embodiment of the present disclosure, a thickness of the flexible substrate ranges from 3 μm to 100 μm.

In the array substrate provided by the embodiment of the present disclosure, film layer thicknesses of the buffer layer and the flexible substrate are same.

In the array substrate provided by the embodiment of the present disclosure, a structure of the thin film transistor includes a back channel etch type, an etch stopper type, and a top-gate structure type.

In the array substrate provided by the embodiment of the present disclosure, the thin film transistor further includes an active layer and source and drain electrodes, the active layer is disposed under the gate electrode, and the source and drain electrodes are disposed at both sides of the gate electrode.

In the array substrate provided by the embodiment of the present disclosure, a material of the active layer includes one of amorphous silicon, low temperature polysilicon, or metal oxide semiconductors.

In the array substrate provided by the embodiment of the present disclosure, a material of the pixel electrode includes indium tin oxide.

An embodiment of the present disclosure further provides a display panel, which includes the array substrate in the above embodiment and a chip on film disposed under the array substrate, wherein the chip on film is bonded to the bonding wirings.

In the display panel provided by the embodiment of the present disclosure, the display panel is a liquid crystal display panel further including a color filter substrate disposed opposite to the array substrate and a plurality of liquid crystal molecules disposed between the array substrate and the color filter substrate.

In the display panel provided by the embodiment of the present disclosure, the display panel is an organic light-emitting diode (OLED) display panel including a light-emitting functional layer disposed on the array substrate and an encapsulation layer disposed on the light-emitting functional layer.

An embodiment of the present disclosure further provides a manufacturing method of an array substrate, which includes following steps. Step S10: providing a glass substrate divided into a display area and a bending area, manufacturing a buffer layer on one side of the glass substrate, and manufacturing a flexible substrate on another side of the glass substrate, wherein the buffer layer and a part of the flexible substrate are disposed corresponding to the display area, and another part of the flexible substrate is disposed corresponding to the bending area. Step S20: manufacturing a thin film transistor and a pixel electrode on the buffer layer and the flexible substrate in the display area, and when manufacturing the thin film transistor, manufacturing a plurality of signal lines in the display area and a plurality of bonding wirings on the flexible substrate in the bending area at a same time, wherein the signal lines are respectively connected to the bonding wirings. Step S30: removing the glass substrate corresponding to the bending area, and bending and fixing the exposed flexible substrate to one surface of the glass substrate away from the thin film transistor.

In the manufacturing method of the array substrate provided by the embodiment of the present disclosure, a material of the flexible substrate includes polyimide.

In the manufacturing method of the array substrate provided by the embodiment of the present disclosure, a thickness of the flexible substrate ranges from 3 μm to 100 μm.

In the manufacturing method of the array substrate provided by the embodiment of the present disclosure, film layer thicknesses of the buffer layer and the flexible substrate are same.

In the manufacturing method of the array substrate provided by the embodiment of the present disclosure, a structure of the thin film transistor includes a back channel etch type, an etch stopper type, and a top-gate structure type.

In the manufacturing method of the array substrate provided by the embodiment of the present disclosure, the thin film transistor further includes an active layer and source and drain electrodes, the active layer is disposed under a gate electrode, and the source and drain electrodes are disposed at both sides of the gate electrode.

In the manufacturing method of the array substrate provided by the embodiment of the present disclosure, a material of the active layer includes one of amorphous silicon, low temperature polysilicon, or metal oxide semiconductors.

In the manufacturing method of the array substrate provided by the embodiment of the present disclosure, in the step S30, a method of removing the glass substrate corresponding to the bending area includes at least one of substrate thinning technique, cutting, or laser ablation.

In the manufacturing method of the array substrate provided by the embodiment of the present disclosure, in the step S30, a fixing material for fixing the exposed flexible substrate includes at least one of double-sided tapes or glues.

Beneficial effects of the present disclosure are that in the array substrate, the manufacturing method thereof, and the display panel provided by the present disclosure, the flexible substrate is manufactured on one side of the glass substrate of the array substrate, and when the thin film transistor is manufactured on the glass substrate, the bonding wirings are manufactured on the flexible substrate at a same time. After finishing array processes of the array substrate, the glass substrate corresponding to the bending area is removed, and the flexible substrate manufactured with the bonding wirings is bent to a back surface of the glass substrate to perform COF bonding, thereby realizing a bezel-free design and preventing using nano silver glues in a bonding process. Therefore, a lower yield problem caused by using the nano silver glues in the bonding process for current array substrates to realize narrow bezels or bezel-free is solved.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic cross-sectional film layer structural diagram of an array substrate before bending a bending area according to an embodiment of the present disclosure.

FIG. 2 is a schematic film layer structural diagram of a thin film transistor according to an embodiment of the present disclosure.

FIG. 3 is a partial schematic structural top view of the array substrate according to an embodiment of the present disclosure.

FIG. 4 is a schematic film layer structural diagram of the array substrate after bending the bending area according to an embodiment of the present disclosure.

FIG. 5 is a flowchart of a manufacturing method of an array substrate according to an embodiment of the present disclosure.

FIGS. 6 and 7 are schematic film layer structural diagrams of the array substrate in each step of the manufacturing method of the array substrate according to an embodiment of the present disclosure.

FIG. 8 is a first schematic structural diagram of a display panel according to an embodiment of the present disclosure.

FIG. 9 is a second schematic structural diagram of the display panel according to an embodiment of the present disclosure.

### DETAILED DESCRIPTION OF PREFERRED EMBODIMENTS

The specific embodiments described with reference to the attached drawings are all exemplary and are intended to illustrate and interpret the present disclosure. In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. Therefore, the directional terms used are to illustrate and understand the present disclosure, not to limit the present disclosure. The identical or similar reference numerals constantly denote the identical or similar elements or elements having the identical or similar functions in the drawings. In the drawings, the sizes and thicknesses of some components are exaggerated for understanding and ease of description.

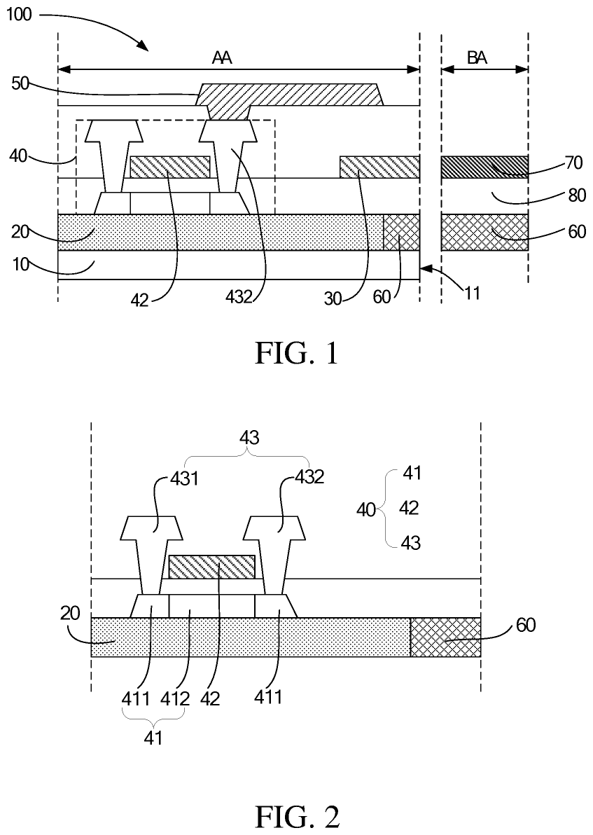

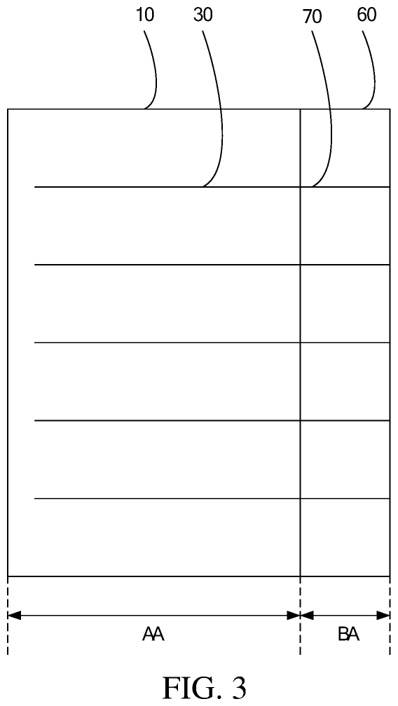

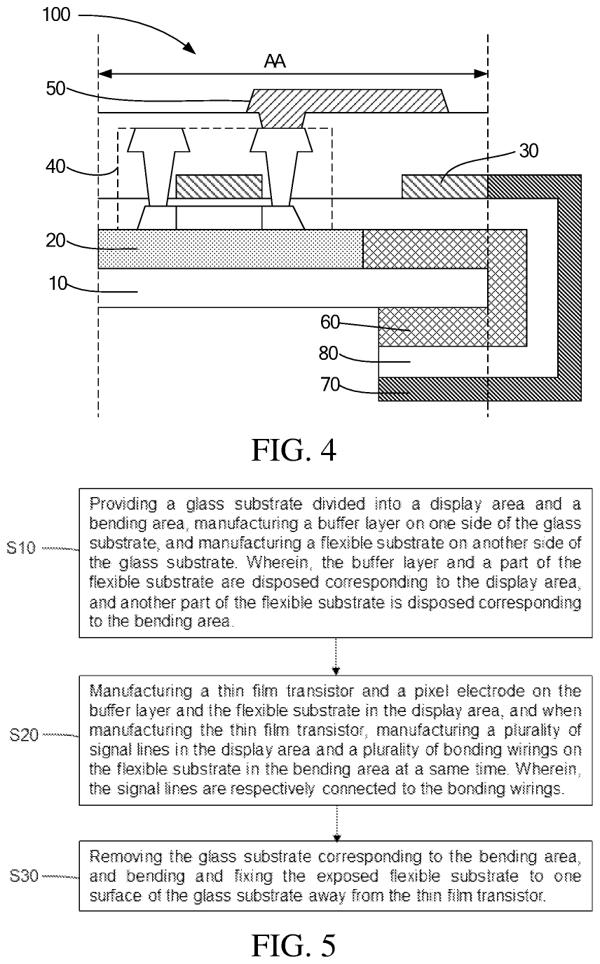

Referring to FIGS. 1 and 2, in an embodiment, an array substrate 100 is provided. As shown in FIG. 1, the array substrate 100 is divided into a display area AA and a bending area BA, and the bending area BA is positioned on one side of the display area AA. The array substrate 100 includes a glass substrate 10 and a flexible substrate 60. The glass substrate 10 corresponds to the display area AA, and the flexible substrate 60 corresponds to the bending area BA and extends from the bending area BA to cover an upper surface of one side 11 of the glass substrate 10 in the display area AA. Wherein, the display area AA further includes a buffer layer 20, a thin film transistor 40, a plurality of signal lines 30, and a pixel electrode 50. The buffer layer 20 is disposed on the glass substrate 10 and is in contact with the flexible substrate 60. The thin film transistor 40 is disposed on the buffer layer 20 and the flexible substrate 60. The plurality of signal lines 30 are disposed on a same layer as a gate electrode 42 of the thin film transistor 40. The pixel electrode 50 is disposed on the thin film transistor 40 and is connected to the thin film transistor 40. The bending area BA further includes a plurality of bonding wirings 70 disposed on the flexible substrate 60 (FIG. 1 is a schematic film layer structural diagram of the array substrate and shows a schematic cross-sectional view of the bonding wirings 70 and the signal lines 30, while FIG. 3 is a partial schematic structural top view of the array substrate and shows electrical connections between the plurality of bonding wirings 70 and the plurality of signal lines 30). The plurality of bonding wirings 70 are respectively connected to the plurality of signal lines 30 in the display area AA. Wherein, the flexible substrate 60 in the bending area BA is bent along the one side 11 of the glass substrate 10 to one surface of the glass substrate 10 away from the thin film transistor 40, as shown in FIG. 4.

Specifically, a structure of the thin film transistor includes a back channel etch (BCE) type, an etch stopper (etch stop layer, ESL) type, and a top-gate structure type.

Specifically, the thin film transistor 40 shown in FIGS. 1 and 2 as a top-gate structure is taken as an example. Specifically, as shown in FIG. 2, the thin film transistor 40 includes an active layer 41, a gate electrode 42, and source and drain electrodes 43. The gate electrode 42 is disposed on the active layer 41. The source and drain electrodes 43 are disposed at both sides of the gate electrode 42 and include a source electrode 431 and a drain electrode 432. The active layer 41 includes doped areas 411 and a channel area 412, and the source electrode 431 and the drain electrode 432 are respectively connected to the doped areas 411 of the active layer 41.

Specifically, the active layer 41 may use amorphous silicon (a-Si), low temperature polysilicon (LTPS), or metal oxide semiconductors such as indium gallium zinc oxide (IGZO).

Specifically, referring to FIGS. 1 and 2, the plurality of signal lines 30 are manufactured in the display area AA and are disposed on the same layer as the gate electrode 42 of the thin film transistor 40. In addition, the signal lines 30 are connected to the bonding wirings 70 in the bending area BA. A film layer between the bonding wirings 70 and the flexible substrate 60 may include an insulating layer 80 in normal processes of thin film transistors, such as a gate electrode insulating layer. Of course, a connection method between the signal lines and the bonding wirings of the present disclosure is not limited to that shown in FIG. 1. The bonding wirings may form with the signal lines at a same time, and the bonding wirings can be extensions of the signal lines. Alternatively, the signal lines may be connected to the bonding wirings by defining through-holes in the gate electrode insulating layer. Alternatively, if the thin film transistor uses a bottom-gate structure, the signal lines may be directly disposed on surfaces of the buffer layer 20 and the flexible substrate 60, and directly connected to the bonding wirings.

Further, a partial schematic structural top view of connections between the signal lines 30 and the bonding wirings 70 is shown in FIG. 3. For ease of description, FIG. 3 only shows the signal lines 30, the bonding wirings 70, the glass substrate 10, and the flexible substrate 60. The signal lines 30 are disposed on the glass substrate 10 and fan out to the bending area BA at junctions of the display area AA and the bending area BA to be respectively connected to the bonding wirings 70 on the flexible substrate 60 in the bending area BA.

Specifically, the signal lines include gate electrode lines and data lines, and the signal lines shown in FIGS. 1 and 2 are the gate electrode lines.

Further, the array substrate 100 also includes the pixel electrode 50 disposed on the thin film transistor 40. The pixel electrode 50 may be connected to the source electrode 431 or the drain electrode 432 through a through-hole. FIGS. 1 and 2 show that the pixel electrode 50 is connected to the drain electrode 432. Of course, the array substrate also includes a plurality of the insulating layers disposed between each film layer of the thin film transistor and the pixel electrode. However, the insulating layers are current technology and are not the focus of the present disclosure, so they are not specifically marked or shown in the figures and will not be repeated here.

Specifically, a material of the pixel electrode includes transparent conductive electrode materials, such as indium tin oxide (ITO).

Specifically, the buffer layer 20 in the display area AA is disposed on the glass substrate 10 and on a same layer as the flexible substrate 60, and upper surfaces of the buffer layer 20 and the flexible substrate 60 are on a same horizontal plane, that is, film layer thicknesses of the two are same. As such, height differences between the bonding wirings 70 and the signal lines 30 can be well balanced, thereby preventing step differences. Of course, the film layer thicknesses of the buffer layer and the flexible substrate may also be different according to actual process requirements.

Further, a material of the flexible substrate 60 in the bending area BA includes bendable flexible materials, such as polyimide (PI).

Further, a thickness of the flexible substrate 60 may be set according to actual process requirements and ranges from 3 μm to 100 μm.

Further, the flexible substrate 60 may be bent to a back surface of the glass substrate 10 and be fixed onto the back surface of the glass substrate 10 by fixing methods such as a double-sided tape or a glue to conveniently perform COF bonding.

In this embodiment, a substrate of the array substrate uses a method of combining the glass substrate and the flexible substrate to manufacture the bonding wirings on the flexible substrate. The flexible substrate manufactured with the bonding wirings can be bent to the back surface of the glass substrate to perform the COF bonding, thereby realizing a bezel-free design and preventing a lower yield problem caused by using nano silver glues.

In an embodiment of the present disclosure, a manufacturing method of an array substrate is further provided, as shown in FIG. 5, which includes following steps.

Step S10: providing a glass substrate divided into a display area and a bending area, manufacturing a buffer layer on one side of the glass substrate, and manufacturing a flexible substrate on another side of the glass substrate. Wherein, the buffer layer and a part of the flexible substrate are disposed corresponding to the display area, and another part of the flexible substrate is disposed corresponding to the bending area.

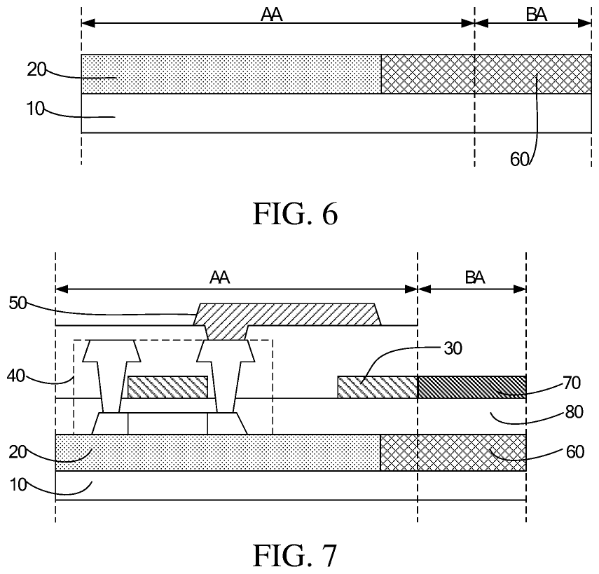

Specifically, according to actual process requirements, an inorganic film layer is deposited on one side of the glass substrate 10 as the buffer layer 20, and a flexible film layer is deposited on another side of the glass substrate 10 as the flexible substrate 60 by deposition processes, such as chemical vapor deposition (CVD). The flexible substrate 60 extends from the bending area BA to the display area AA and is in contact with the buffer layer 20, as shown in FIG. 6.

Further, a material of the flexible substrate 60 includes bendable flexible materials, such as polyimide.

Further, a thickness of the flexible substrate 60 may be set according to actual process requirements and ranges from 3 μm to 100 μm.

Specifically, the buffer layer 20 in the display area AA is disposed on the glass substrate 10 and on a same layer as the flexible substrate 60, so height differences between a plurality of bonding wirings and a plurality of signal lines can be well balanced, thereby preventing step differences.

Step S20: manufacturing a thin film transistor and a pixel electrode on the buffer layer and the flexible substrate in the display area, and when manufacturing the thin film transistor, manufacturing the plurality of signal lines in the display area and the plurality of bonding wirings on the flexible substrate in the bending area at a same time, wherein the signal lines are respectively connected to the bonding wirings.

Specifically, as shown in FIG. 7, the buffer layer 20 and a part of the flexible substrate 60 are manufactured on the glass substrate 10 in the display area AA. The thin film transistor 40 and the pixel electrode 50 are manufactured on the buffer layer 20 and the part of the flexible substrate 60.

Specifically, as shown in FIG. 2, the thin film transistor 40 includes an active layer 41, a gate electrode 42, and source and drain electrodes 43. The gate electrode 42 is disposed on the active layer 41. The source and drain electrodes 43 are disposed at both sides of the gate electrode 42 and include a source electrode 431 and a drain electrode 432. The active layer 41 includes doped areas 411 and a channel area 412, and the source electrode 431 and the drain electrode 432 are respectively connected to the doped areas 411 of the active layer 41.

Specifically, the active layer 41 may use amorphous silicon (a-Si), low temperature polysilicon (LTPS), or metal oxide semiconductors such as indium gallium zinc oxide (IGZO).

Further, when manufacturing the thin film transistor 40 on the buffer layer 20 and the part of the flexible substrate 60, the plurality of signal lines 30 are manufactured in the display area AA, and the plurality of bonding wirings 70 are manufactured on the flexible substrate 60 in the bending area BA. An insulating layer 80 is further disposed between the bonding wirings 70 and the flexible substrate 60, and the signal lines 30 are respectively connected to the bonding wirings 70, as shown in FIG. 7.

Further, the pixel electrode 50 is connected to the source electrode or the drain electrode through a through-hole. Of course, the array substrate also includes a plurality of the insulating layers disposed between each film layer of the thin film transistor and the pixel electrode, which will not be repeated here.

Specifically, a material of the pixel electrode includes transparent conductive electrode materials, such as indium tin oxide (ITO).

Step S30: removing the glass substrate corresponding to the bending area, and bending and fixing the exposed flexible substrate to one surface of the glass substrate away from the thin film transistor.

Specifically, the glass substrate 10 corresponding to the bending area BA is removed by using at least one process of substrate thinning technique, cutting, or laser ablation to form a structure shown in FIG. 1.

Further, as shown in FIG. 4, after removing the glass substrate corresponding to the bending area, the flexible substrate 60 manufactured with the bonding wirings 70 is bent to a back surface of the glass substrate 10 (that is, the one surface of the glass substrate 10 away from the thin film transistor 40).

Further, the flexible substrate bent to the back surface of the glass substrate is fixed onto the glass substrate by a double-sided tape, a glue, or other fixing methods.

In an embodiment of the present disclosure, a display panel is further provided, which includes the array substrate in the above embodiments and a chip on film disposed under the array substrate. Wherein, the chip on film is bonded to the bonding wirings.

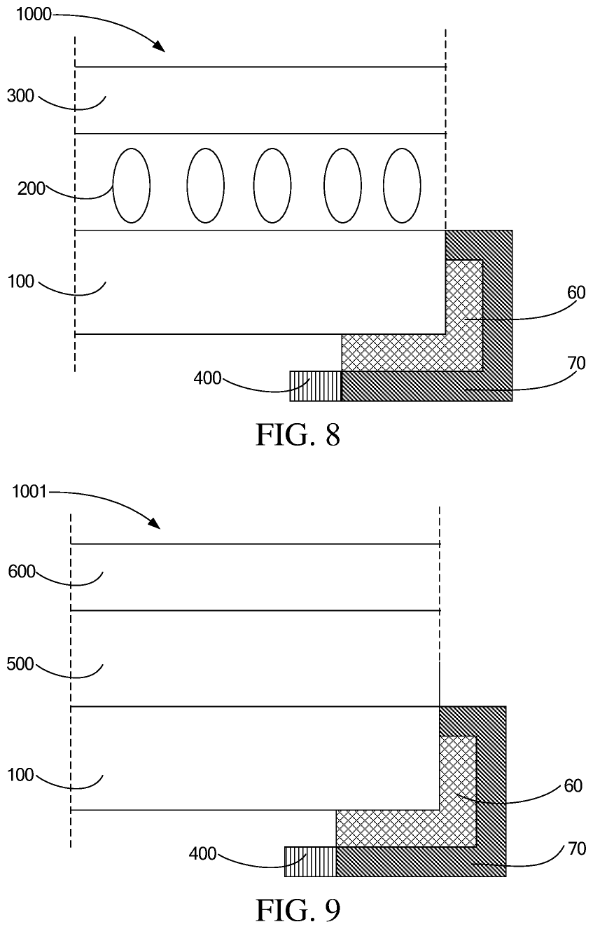

Specifically, the display panel is a liquid crystal display panel shown in FIG. 8. The liquid crystal display panel 1000 includes the array substrate 100, a color filter substrate 300 disposed opposite to the array substrate 100, and a plurality of liquid crystal molecules 200 disposed between the array substrate 100 and the color filter substrate 300. The liquid crystal display panel 1000 further includes the chip on film 400 bonded to the bonding wirings 70 on the flexible substrate 60.

Specifically, the display panel is an organic light-emitting diode (OLED) display panel shown in FIG. 9. The OLED display panel 1001 includes the array substrate 100, a light-emitting functional layer 500 disposed on the array substrate 100, and an encapsulation layer 600 disposed on the light-emitting functional layer 500. The OLED display panel 1001 further includes the chip on film 400 bonded to the bonding wirings 70 on the flexible substrate 60.

It should be noted that the present disclosure uses a method of combining the glass substrate and the flexible substrate to manufacture the bonding wirings on the flexible substrate. Then, the flexible substrate manufactured with the bonding wirings is bent to the back surface of the glass substrate to perform the chip on film (COF) bonding. A method to realize the bezel-free design is not limited to the array substrate provided by the embodiments of the present disclosure. This bezel-free design method is also applicable to a gate driver on array (GOA) substrate or a color filter on array (COA) substrate, which is not repeated herein.

It can be known according to the above embodiments:

the present disclosure provides the array substrate, the manufacturing method thereof, and the display panel. The flexible substrate is manufactured on one side of the glass substrate of the array substrate, and when the thin film transistor is manufactured on the glass substrate, the bonding wirings are manufactured on the flexible substrate at a same time. After finishing array processes of the array substrate, the glass substrate under the flexible substrate is removed, and the flexible substrate is bent to the back surface of the glass substrate to perform COF bonding, thereby realizing the bezel-free design and preventing using nano silver glues in the bonding process. Therefore, a lower yield problem caused by using the nano silver glues in the bonding process for current array substrates to realize narrow bezels or bezel-free is solved.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. An array substrate, divided into a display area and a bending area positioned on one side of the display area and comprising a glass substrate and a flexible substrate, wherein the glass substrate corresponds to the display area, and the flexible substrate corresponds to the bending area and extends from the bending area to cover an upper surface of one side of the glass substrate in the display area; wherein the display area further comprises:
a buffer layer disposed on the glass substrate and in contact with the flexible substrate;
a thin film transistor disposed on the buffer layer and the flexible substrate;
a plurality of signal lines disposed on a same layer as a gate electrode of the thin film transistor; and
a pixel electrode disposed on the thin film transistor and connected to the thin film transistor;
wherein the bending area further comprises a plurality of bonding wirings disposed on the flexible substrate and respectively connected to the signal lines in the display area; and
wherein the flexible substrate in the bending area is bent along the one side of the glass substrate to one surface of the glass substrate away from the thin film transistor.

2. The array substrate according to claim 1, wherein a material of the flexible substrate comprises polyimide.

3. The array substrate according to claim 1, wherein a thickness of the flexible substrate ranges from 3 μm to 100 μm.

4. The array substrate according to claim 1, wherein film layer thicknesses of the buffer layer and the flexible substrate are same.

5. The array substrate according to claim 1, wherein a structure of the thin film transistor comprises a back channel etch type, an etch stopper type, and a top-gate structure type.

6. The array substrate according to claim 5, wherein the thin film transistor further comprises an active layer and source and drain electrodes, the active layer is disposed under the gate electrode, and the source and drain electrodes are disposed at both sides of the gate electrode.

7. The array substrate according to claim 6, wherein a material of the active layer comprises one of amorphous silicon, low temperature polysilicon, or metal oxide semiconductors.

8. The array substrate according to claim 1, wherein a material of the pixel electrode comprises indium tin oxide.

9. A display panel, comprising the array substrate according to claim 1 and a chip on film disposed under the array substrate, wherein the chip on film is bonded to the bonding wirings.

10. The display panel according to claim 9, being a liquid crystal display panel comprising a color filter substrate disposed opposite to the array substrate and a plurality of liquid crystal molecules disposed between the array substrate and the color filter substrate.

11. The display panel according to claim 9, being an organic light-emitting diode (OLED) display panel comprising a light-emitting functional layer disposed on the array substrate and an encapsulation layer disposed on the light-emitting functional layer.

12. A manufacturing method of an array substrate, comprising following steps:
step S10: providing a glass substrate divided into a display area and a bending area, manufacturing a buffer layer on one side of the glass substrate, and manufacturing a flexible substrate on another side of the glass substrate, wherein the buffer layer and a part of the flexible substrate are disposed corresponding to the display area, and another part of the flexible substrate is disposed corresponding to the bending area;
step S20: manufacturing a thin film transistor and a pixel electrode on the buffer layer and the flexible substrate in the display area, and when manufacturing the thin film transistor, manufacturing a plurality of signal lines in the display area and a plurality of bonding wirings on the flexible substrate in the bending area at a same time, wherein the signal lines are respectively connected to the bonding wirings; and
step S30: removing the glass substrate corresponding to the bending area, and bending and fixing the exposed flexible substrate to one surface of the glass substrate away from the thin film transistor.

13. The manufacturing method of the array substrate according to claim 12, wherein a material of the flexible substrate comprises polyimide.

14. The manufacturing method of the array substrate according to claim 12, wherein a thickness of the flexible substrate ranges from 3 μm to 100 μm.

15. The manufacturing method of the array substrate according to claim 12, wherein film layer thicknesses of the buffer layer and the flexible substrate are same.

16. The manufacturing method of the array substrate according to claim 12, wherein a structure of the thin film transistor comprises a back channel etch type, an etch stopper type, and a top-gate structure type.

17. The manufacturing method of the array substrate according to claim 16, wherein the thin film transistor further comprises an active layer and source and drain electrodes, the active layer is disposed under a gate electrode, and the source and drain electrodes are disposed at both sides of the gate electrode.

18. The manufacturing method of the array substrate according to claim 17, wherein a material of the active layer comprises one of amorphous silicon, low temperature polysilicon, or metal oxide semiconductors.

19. The manufacturing method of the array substrate according to claim 12, wherein in the step S30, a method of removing the glass substrate corresponding to the bending area comprises at least one of substrate thinning technique, cutting, or laser ablation.

20. The manufacturing method of the array substrate according to claim 12, wherein in the step S30, a fixing material for fixing the exposed flexible substrate comprises at least one of double-sided tapes or glues.
